(19) United States
(12) Patent Application Publication
(10) Pub. No.: US 2026/0043882 A1
(43) Pub. Date: Feb. 12, 2026

(54) Phase Correction Method and Apparatus for Magnetic Resonance Imaging, and System

(71) Applicant: Siemens Healthineers AG, Forchheim (DE)

(72) Inventors: Li Yang, Shenzhen (CN); Kun Zhou, Shenzhen (CN); De He Weng, Shenzhen (CN)

(73) Assignee: Siemens Healthineers AG, Forchheim (DE)

(21) Appl. No.: 19/293,268

(22) Filed: Aug. 7, 2025

(30) Foreign Application Priority Data
Aug. 8, 2024 (CN) 202411091213.X

(51) Int. Cl. G01R 33/565; G01R 33/56

(52) U.S. Cl. CPC G01R 33/56545; G01R 33/5608

(57) ABSTRACT

Techniques are described for performing a phase correction for magnetic resonance imaging. The techniques include: for each slice of a target site: using a channel compression algorithm to determine each virtual channel of the slice using a channel compression matrix; determining a main virtual channel of the slice from each virtual channel; using phase correction data of the main virtual channel of the slice of the target site to perform phase correction on multi-segment image data of each virtual channel of the slice of the target site. This results in a reduction in phase errors in multi-segment MR image data.

### CROSS-REFERENCE TO RELATED APPLICATIONS

The present application claims priority to and the benefit of China patent application no. CN 202411091213.X, filed on Aug. 8, 2024, the contents of which are incorporated herein by reference in their entirety.

### TECHNICAL FIELD

The present disclosure relates to the technical field of magnetic resonance (MR) and, in particular, to a method, apparatus, and system to perform MR imaging using phase correction.

### BACKGROUND

When acquiring MR image data, segmented acquisition with multiple excitations is often employed, i.e. for each slice of a target site, a first segment of the slice is acquired first, a second segment of the slice is then acquired, and then a third segment of the slice is acquired, and so on, until finally all the segments of the slice are combined to obtain a complete dataset of the slice. Segmented scan sequences may be implemented using pulse sequences. That is, k-space lines corresponding to each segment of each slice in different gradient echoes or spin echoes are read out and combined into a complete k-space of each slice. For example, a TSE (turbo spin echo) sequence is a more common segmented scan sequence; at each excitation, first a 90° RF (radio frequency) pulse is transmitted, and subsequently, multiple 180° refocusing pulses are transmitted to generate multiple spin echoes that respectively depict different lines in k-space.

Factors such as magnetic field non-uniformity, eddy current effects, slight time shifts, or other similar effects, may cause different segments to have their own phase evolution. If these segments are combined into a complete dataset without additional phase correction, artifacts may appear in MR images that are reconstructed from the complete dataset of each slice. In TSE imaging, each spin echo may have a certain phase error due to a dynamic interference field occurring during an echo sequence, resulting in artifacts in an MR image.

To reduce this type of artifact, phase correction can be performed on the image data of different segments. Before image data is acquired, phase correction data of each slice is first acquired using a scan sequence that does not apply a phase-encoding gradient, and then the phase correction data of each slice is used to perform phase correction on the acquired image data of each segment of each slice, thereby reducing the effect of different phase errors.

Parallel imaging uses a phased array coil for faster scanning. In parallel imaging, the spatial correlation (also known as sensitivity) of B1 fields of a receiving coil array is used to remove or prevent aliasing. Since different coil units have a certain sensitivity difference in the phase-encoding direction, this feature can be used to separate signals that are aliased together.

The current phase correction method for multi-segment TSE respectively uses the phase correction data of each coil channel to correct the image data of the corresponding coil channel. When the quality of the acquired phase correction data is not high, this may result in incomplete phase correction between echoes or the introduction of additional phase differences between channels, which may result in artifacts in the MR image obtained by image reconstruction of the phase-corrected image data using a parallel imaging algorithm.

### SUMMARY

FIG. 1 illustrates an existing example of MR images obtained by using phase correction data of each coil channel to correct image data of a corresponding coil channel, and then performing image reconstruction on the phase-corrected image data using a parallel imaging algorithm. In FIGS. 1, 11 and 12 are both prostate images. The parallel imaging acceleration factor used for 11 is 4, and the parallel imaging acceleration factor used for 12 is 3. Moreover, 13 is a cervical vertebra image with the parallel imaging acceleration factor used therefor is 2. The reference image 14 is a knee image using a parallel imaging acceleration factor of 3. The red arrows in 11-14 point to artifacts in the images. The artifacts in FIG. 1 are mainly due to the low quality of the phase correction data of certain channels, which introduces an additional phase difference between channels.

FIG. 2 illustrates an existing example of an image obtained by using low-quality phase correction data to perform phase correction on image data, and then performing image reconstruction on the phase-corrected image data using a parallel imaging algorithm, wherein the imaging target is a water phantom. Here, the white circle in the center of FIG. 2 is a water phantom, and it can be seen that artifacts appear directly above and directly below the water phantom.

In view of this, one aspect of embodiments of the present disclosure proposes a phase correction method and apparatus for MR imaging to reduce phase errors in multi-segment MR image data; another aspect proposes an MR imaging system to reduce phase errors in multi-segment MR image data; and a further aspect proposes a computer program product, a computer-readable storage medium, and an electronic device to reduce phase errors in multi-segment MR image data.

A phase correction method for magnetic resonance imaging, the method comprising: for each slice of a target site:
using a channel compression algorithm to determine each virtual channel of the slice using a channel compression matrix;
determining a main virtual channel of the slice from each virtual channel; and
using phase correction data of the main virtual channel of the slice of the target site to perform phase correction on multi-segment image data of each virtual channel of the slice of the target site.

The step of using a channel compression algorithm to determine each virtual channel of the slice using a channel compression matrix comprises:
using a channel compression algorithm to perform a calculation on ACS of each physical channel of the slice of the target site, to obtain a channel compression matrix of the slice of the target site, and using the channel compression matrix to obtain ACS of each virtual channel of the slice of the target site;
the step of determining a main virtual channel of the slice from each virtual channel comprises:
searching all the virtual channels of the slice for a virtual channel containing optimal ACS information, according to ACS of each virtual channel of the slice of the target site, and taking the virtual channel containing the optimal ACS information to be the main virtual channel of the slice.

The step of using phase correction data of the main virtual channel of the slice of the target site to perform phase correction on multi-segment image data of each virtual channel of the slice of the target site comprises:
using a channel compression matrix of the slice of the target site to perform channel compression on phase correction data of each physical channel of the slice of the target site, to obtain phase correction data of each virtual channel of the slice of the target site; using the channel compression matrix of the slice of the target site to perform channel compression on multi-segment image data of each physical channel of the slice of the target site, to obtain multi-segment image data of each virtual channel of the slice of the target site; and using the phase correction data of the main virtual channel of the slice of the target site to perform phase correction on the multi-segment image data of each virtual channel of the slice of the target site.

After the step of using phase correction data of the main virtual channel of the slice of the target site to perform phase correction on multi-segment image data of each virtual channel of the slice of the target site, the method further comprises:
using a parallel imaging algorithm to perform image reconstruction on the multi-segment image data of each virtual channel of each slice of the target site after phase correction, to obtain a magnetic resonance image.

The channel compression algorithm is:
a geometric channel/coil compression GCC algorithm, or a single coil compression SCC algorithm, or a mode matrix algorithm.

The step of searching all the virtual channels of the slice for a virtual channel containing optimal ACS information, according to ACS of each virtual channel of the slice of the target site, and taking the virtual channel containing the optimal ACS information to be the main virtual channel of the slice comprises:
searching for ACS with the largest amplitude in all k-spaces where ACS of all virtual channels of the slice is located, and taking the virtual channel where ACS with the largest amplitude is located to be the main virtual channel of the slice;
alternatively, respectively calculating the sum of squares for a preset number of ACS of each k-space central region where ACS of each virtual channel of the slice is located, searching for a maximum value in the sum of squares corresponding to each virtual channel, and taking the virtual channel where the maximum value is located to be the main virtual channel of the slice.

The step of using phase correction data of the main virtual channel of the slice of the target site to perform phase correction on multi-segment image data of each virtual channel of the slice of the target site comprises:
calculating a phase difference between a first echo and each subsequent echo of the main virtual channel of the slice, respectively, according to phase correction data of each subsequent echo of the main virtual channel of the slice, with reference to phase correction data of the first echo of the main virtual channel of the slice of the target site; and
performing phase correction on multi-segment image data of each subsequent echo of each virtual channel of the slice of the target site, according to the calculated phase difference between the first echo and each subsequent echo of the main virtual channel of the slice.

A phase correction apparatus for magnetic resonance imaging, the apparatus comprising:
a main virtual channel searching module, used for: for each slice of a target site, using a channel compression algorithm to determine each virtual channel of the slice using a channel compression matrix; and determining a main virtual channel of the slice from each virtual channel; and
a phase correction module, used for: for each slice of the target site, using phase correction data of the main virtual channel of the slice of the target site to perform phase correction on multi-segment image data of each virtual channel of the slice of the target site.

The main virtual channel searching module using a channel compression algorithm to determine each virtual channel of the slice using a channel compression matrix; and determining a main virtual channel of the slice from each virtual channel comprises:
using a channel compression algorithm to perform a calculation on ACS of each physical channel of the slice of the target site, to obtain a channel compression matrix of the slice of the target site, and using the channel compression matrix to obtain ACS of each virtual channel of the slice of the target site; and searching all the virtual channels of the slice for a virtual channel containing optimal ACS information, according to ACS of each virtual channel of the slice of the target site, and taking the virtual channel containing the optimal ACS information to be the main virtual channel of the slice.

The phase correction module using phase correction data of the main virtual channel of the slice of the target site to perform phase correction on multi-segment image data of each virtual channel of the slice of the target site comprises:
using a channel compression matrix of the slice of the target site to perform channel compression on phase correction data of each physical channel of the slice of the target site, to obtain phase correction data of each virtual channel of the slice of the target site; using the channel compression matrix of the slice of the target site to perform channel compression on multi-segment image data of each physical channel of the slice of the target site, to obtain multi-segment image data of each virtual channel of the slice of the target site; and using the phase correction data of the main virtual channel of the slice of the target site to perform phase correction on the multi-segment image data of each virtual channel of the slice of the target site.

The apparatus further comprises: a parallel imaging module, used for using a parallel imaging algorithm to perform image reconstruction on the multi-segment image data of cach virtual channel of each slice of the target site after phase correction, to obtain a magnetic resonance image.

The channel compression algorithm used by the main virtual channel searching module is:
a geometric channel/coil compression GCC algorithm, or a single coil compression SCC algorithm, or a mode matrix algorithm.

The main virtual channel searching module searching all the virtual channels of the slice for a virtual channel containing optimal ACS information, according to ACS of each virtual channel of the slice of the target site, and taking the virtual channel containing the optimal ACS information to be the main virtual channel of the slice comprises:
searching for ACS with the largest amplitude in all k-spaces where ACS of all virtual channels of the slice of the target site is located, and taking the virtual channel where ACS with the largest amplitude is located to be the main virtual channel of the slice;
alternatively, respectively calculating the sum of squares for a preset number of ACS of each k-space central region where ACS of each virtual channel of the slice of the target site is located, searching for a maximum value in the sum of squares corresponding to each virtual channel, and taking the virtual channel where the maximum value is located to be the main virtual channel of the slice.

The phase correction module using phase correction data of the main virtual channel of the slice of the target site to perform phase correction on multi-segment image data of each virtual channel of the slice of the target site comprises:
calculating a phase difference between a first echo and each subsequent echo of the main virtual channel of the slice, respectively, according to phase correction data of each subsequent echo of the main virtual channel of the slice, with reference to phase correction data of the first echo of the main virtual channel of the slice of the target site; and performing phase correction on the multi-segment image data of each subsequent echo of each virtual channel of the slice of the target site, according to the calculated phase difference between the first echo and each subsequent echo of the main virtual channel of the slice.

A magnetic resonance imaging system, the magnetic resonance imaging system comprising the phase correction apparatus for magnetic resonance imaging as described in any of the embodiments above.

In embodiments of the present disclosure, for each slice of the target site: a channel compression algorithm is used to determine each virtual channel of the slice using a channel compression matrix, and a main virtual channel of the slice is determined from cach virtual channel, so that: the main virtual channel is the optimal channel; thereafter, phase correction data of the main virtual channel of the slice of the target site is used to perform phase correction on multi-segment image data of each virtual channel of the slice of the target site, so that: phase correction data of the main channel containing optimal phase correction data in each slice is used to perform phase correction on multi-segment image data of all channels of the slice, avoiding phase correction errors due to phase correction data of poor quality, while also avoiding additional phase differences introduced between channels during a phase correction process, i.e. reducing phase errors in multi-segment image data, and finally reducing artifacts in an MR image obtained by parallel imaging reconstruction, improving the quality of the MR image

### BRIEF DESCRIPTION OF THE DRAWINGS

Example embodiments of the present disclosure will be described in detail below with reference to the drawings to provide a clearer understanding of the abovementioned and other features and advantages of the present disclosure. In the drawings:

FIG. 1 illustrates a conventional example of MR images obtained using phase correction data of each coil channel to correct image data of a corresponding coil channel, and then performing image reconstruction on the phase-corrected image data using a parallel imaging algorithm;

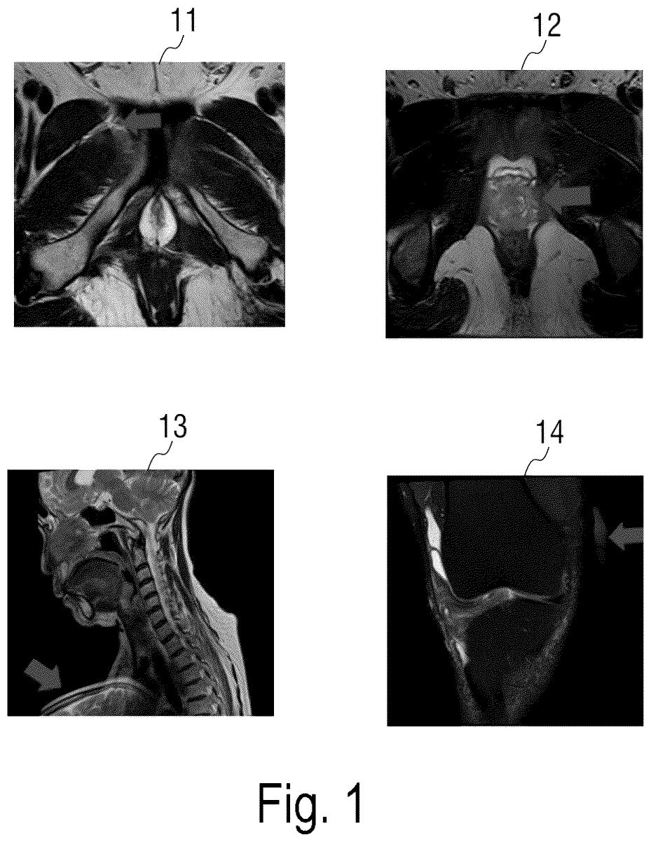

FIG. 2 illustrates a conventional example of an image obtained by using low-quality phase correction data to perform phase correction on image data, and then performing image reconstruction on the phase-corrected image data using a parallel imaging algorithm;

FIG. 3 illustrates an example process flow of a phase correction method for MR imaging as provided in an embodiment of the present disclosure;

FIG. 4 illustrates an example process flow of a phase correction method for MR imaging as provided in another embodiment of the present disclosure;

FIG. 5 illustrates an example process u sed to select a main virtual channel of a certain slice of a target site in an application example of the present disclosure;

FIG. 6 illustrates an example of MR images obtained by using an embodiment of the present disclosure to perform phase correction on acquired multi-segment image data, and then performing image reconstruction on the phase-corrected multi-segment image data using a parallel imaging method, in an application example of the present disclosure;

FIG. 7 illustrates an example of an MR image obtained by using an embodiment of the present disclosure to perform phase correction on acquired multi-segment image data, and then performing image reconstruction on the phase-corrected multi-segment image data using a parallel imaging method, in another application example of the present disclosure;

FIG. 8 illustrates a structural schematic diagram of a phase correction apparatus for MR imaging as provided in an embodiment of the present disclosure.

The reference labels are as follows:

| Label | Meaning |
|---|---|
| 11, 12 | prostate image |
| 13 | cervical vertebra image |
| 14 | knee image |
| 301-304 | steps |
| 401-406 | steps |
| 501-511 | amplitude of each ACS on a central line of a k-space with |
| | respect to ACS corresponding to 11 virtual channels |
| 61, 62 | prostate image |
| 63 | cervical vertebra image |
| 64 | knee image |
| 80 | phase correction apparatus for MR imaging |
| 81 | main virtual channel searching module |
| 82 | phase correction module |
| 83 | parallel imaging module |

### DETAILED DESCRIPTION OF THE DISCLOSURE

To clarify the objective, technical solution, and advantages of the present disclosure, the present disclosure is explained in further detail below by way of embodiments.

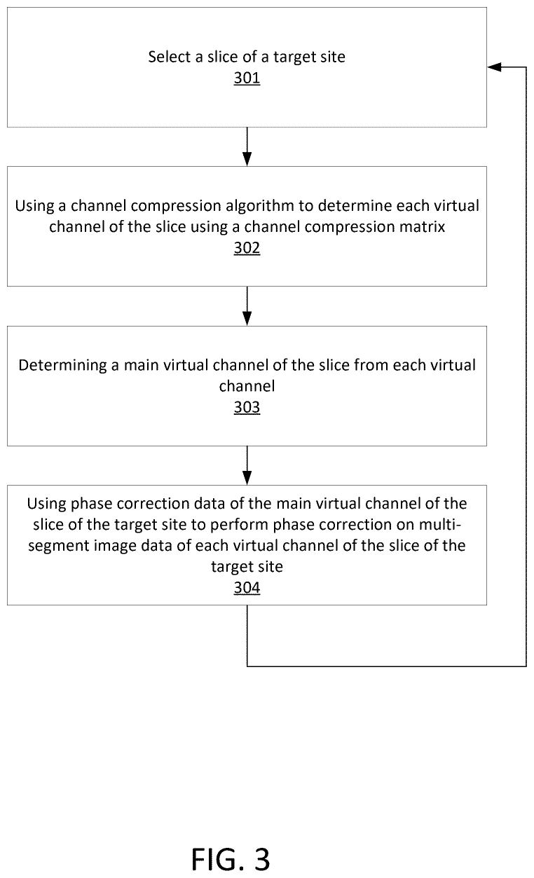

FIG. 3 illustrates an example process flow of a phase correction method for MR imaging as provided in an embodiment of the present disclosure. As shown in FIG. 3, example steps thereof are as follows:

Step 301: for each slice of a target site, respectively executing steps 302-304 as follows:

Step 302: using a channel compression algorithm to determine each virtual channel of the slice using a channel compression matrix.

Step 303: determining a main virtual channel of the slice from each virtual channel.

In an optional embodiment, step 302 may additionally or alternatively comprise: using a channel compression algorithm with principal component analysis to perform a calculation on ACS (auto-calibration signal) of each physical channel of the slice of the target site, to obtain a channel compression matrix of the slice of the target site, and using the channel compression matrix to obtain ACS of each virtual channel of the slice of the target site;

Moreover, step 303 may additionally or alternatively comprise: searching all the virtual channels of the slice for a virtual channel containing optimal ACS information, according to ACS of each virtual channel of the slice of the target site, and taking the virtual channel containing the optimal ACS information to be the main virtual channel of the slice.

In an optional embodiment, the channel compression algorithm with principal component analysis may be for instance a GCC (geometric channel/coil compression) algorithm, an SCC (single coil compression) algorithm, a mode matrix algorithm, etc.

In an optional embodiment, the step of searching all the virtual channels of the slice for a virtual channel containing optimal ACS information, according to ACS of each virtual channel of the slice of the target site, and taking the virtual channel containing the optimal ACS information to be the main virtual channel of the slice comprises: searching for ACS with the largest amplitude in all k-spaces where ACS of all virtual channels of the slice is located, and taking the virtual channel where the ACS with the largest amplitude is located to be the main virtual channel of the slice; or, respectively calculating the sum of squares for a preset number of ACS of each k-space central region where ACS of each virtual channel of the slice is located, searching for a maximum value in the sum of squares corresponding to each virtual channel, and taking the virtual channel where the maximum value is located to be the main virtual channel of the slice.

Step 304: using phase correction data of the main virtual channel of the slice of the target site to perform phase correction on multi-segment image data of each virtual channel of the slice of the target site.

In an optional embodiment, step 304 may additionally or alternatively comprise: using a channel compression matrix of the slice of the target site to perform channel compression on phase correction data of each physical channel of the slice of the target site, to obtain phase correction data of each virtual channel of the slice of the target site; using the channel compression matrix of the slice of the target site to perform channel compression on multi-segment image data of each physical channel of the slice of the target site, to obtain multi-segment image data of each virtual channel of the slice of the target site; and using the phase correction data of the main virtual channel of the slice of the target site to perform phase correction on the multi-segment image data of each virtual channel of the slice of the target site.

In an optional embodiment, the step of using phase correction data of the main virtual channel of the slice of the target site to perform phase correction on multi-segment image data of each virtual channel of the slice of the target site may additionally or alternatively comprise: calculating a phase difference between a first echo and each subsequent echo of the main virtual channel of the slice, respectively, according to phase correction data of cach subsequent echo of the main virtual channel of the slice, with reference to phase correction data of the first echo of the main virtual channel of the slice of the target site; and performing phase correction on the multi-segment image data of each subsequent echo of each virtual channel of the slice of the target site, according to the calculated phase difference between the first echo and each subsequent echo of the main virtual channel of the slice.

In an optional embodiment, after step 304, the method may further comprise: using a parallel imaging algorithm to perform image reconstruction on the multi-segment image data of each virtual channel of each slice of the target site after phase correction, to obtain a magnetic resonance image.

In the above embodiment, for each slice of the target site: a channel compression algorithm may e.g. be used to determine cach virtual channel of the slice using a channel compression matrix, and a main virtual channel of the slice is determined from each virtual channel, so that: the main virtual channel is the optimal channel; thereafter, phase correction data of the main virtual channel of the slice of the target site is used to perform phase correction on multi-segment image data of each virtual channel of the slice of the target site, so that: phase correction data of the main channel containing optimal phase correction data in each slice is used to perform phase correction on multi-segment image data of all channels of the slice, avoiding phase correction errors due to phase correction data of poor quality, while also avoiding additional phase differences introduced between channels during a phase correction process, i.e. reducing phase errors in multi-segment image data, and finally reducing artifacts in an MR image obtained by parallel imaging reconstruction, improving the quality of the MR image.

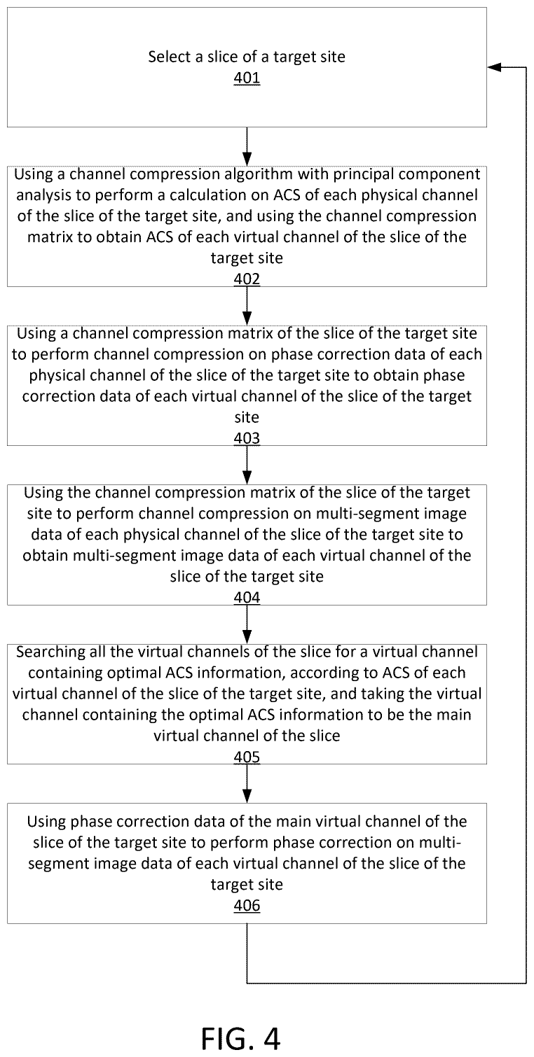

FIG. 4 illustrates an example process flow of a phase correction method for MR imaging as provided in another embodiment of the present disclosure. As shown in FIG. 4, example steps thereof are as follows:

Step 401: for each slice of a target site, respectively executing steps 402-406 as follows:

Step 402: using a channel compression algorithm with principal component analysis to perform a calculation on ACS of each physical channel of the slice of the target site, to obtain a channel compression matrix of the slice of the target site, and using the channel compression matrix to obtain ACS of each virtual channel of the slice of the target site.

In an optional embodiment, a channel compression algorithm with principal component analysis may be for example a GCC algorithm, an SCC algorithm, a mode matrix algorithm, etc. Since compression loss of the GCC algorithm is smaller than that of the other channel compression algorithms, the compression error being almost negligible, in practical applications, the GCC algorithm is more recommended.

Using a channel compression algorithm with principal component analysis, performing a calculation on ACS of each physical channel of the slice of the target site, so that an obtained channel compression matrix contains a factor that can extract a principal component, thereby causing the main virtual channel determined in subsequent step 405 to contain main data information.

Due to channel compression, for each slice of the target site, the number of virtual channels contained in each slice is less than the number of physical channels contained in the slice before channel compression.

Step 403: using a channel compression matrix of the slice of the target site to perform channel compression on phase correction data of each physical channel of the slice of the target site, to obtain phase correction data of each virtual channel of the slice of the target site.

For example, by performing a matrix multiplication on the channel compression matrix of the slice of the target site and the phase correction data of each physical channel of the slice of the target site, the phase correction data of each virtual channel of the slice of the target site can be obtained.

Step 404: using the channel compression matrix of the slice of the target site to perform channel compression on multi-segment image data of each physical channel of the slice of the target site, to obtain multi-segment image data of each virtual channel of the slice of the target site.

For example, by performing a matrix multiplication on the channel compression matrix of the slice of the target site and the multi-segment image data of each physical channel of the slice of the target site, the multi-segment image data of each virtual channel of the slice of the target site can be obtained.

Step 405: searching all the virtual channels of the slice for a virtual channel containing optimal ACS information, according to ACS of each virtual channel of the slice of the target site, and taking the virtual channel containing the optimal ACS information to be the main virtual channel of the slice.

In an optional embodiment, step 405 may additionally or alternatively comprise: searching for ACS with the largest amplitude in all k-spaces where ACS of all virtual channels of the slice is located, and taking the virtual channel where the ACS with the largest amplitude is located to be the main virtual channel; or, respectively calculating the sum of squares for a preset number of ACS of each k-space central region where ACS of each virtual channel of the slice is located, searching for a maximum value in the sum of squares corresponding to each virtual channel, and taking the virtual channel where the maximum value is located to be the main virtual channel.

For example, after the channel compression processing of step 402, the number of channels contained in each slice of the target site changes from m physical channels to q virtual channels, where q<m. Then for a certain slice of the target site, the slice contains q virtual channels. For the ACS, each virtual channel corresponds to a k-space with respect to ACS, that is, there being q k-spaces with respect to ACS, the ACS with the largest amplitude is searched for in each k-space with respect to ACS, respectively, then the q ACS with the largest amplitudes are obtained, then the ACS with the largest amplitude is further selected from the q ACS with the largest amplitude, then the virtual channel where the last-selected ACS with the largest amplitude is located is the main virtual channel of the slice of the target site, wherein each ACS is represented by a complex number, and the modulus of the complex number is the amplitude of the ACS; or, for each k-space, the sum of squares for a preset number of ACS of each k-space central region is calculated (i.e. the sum of squares of the real and imaginary parts of ACS), respectively, to obtain q sum of squares, then the maximum sum of the squares is selected from the q sum of squares, and then the virtual channel where the largest sum of squares is located is the main virtual channel of the slice of the target site.

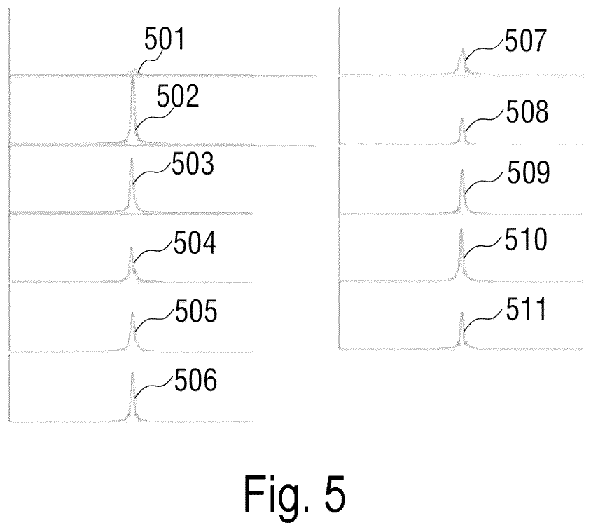

FIG. 5 illustrates an example process used to select a main virtual channel of a certain slice of a target site in an application example of the present disclosure. As shown in FIG. 5, there are 11 virtual channels per slice of the target site, and 501-511 are the amplitudes of each ACS on a central line of a k-space with respect to ACS corresponding to the 11 virtual channels of a certain slice of the target site, respectively. For example, 501 is the amplitude of the respective ACS on the central line of the k-space with respect to ACS corresponding to the first virtual channel. For each virtual channel, ACS with the largest amplitude is searched for in all ACS on the central line of k-space with respect to ACS corresponding thereto, wherein the ACS with the largest amplitude is typically the central point of k-space; as can be seen, the largest amplitude corresponding to 502 is the largest amplitude in all k-spaces, so the second virtual channel corresponding to 502 is the main virtual channel of the slice of the target site.

Step 406: using phase correction data of the main virtual channel of the slice of the target site to perform phase correction on multi-segment image data of each virtual channel of the slice of the target site.

Taking FIG. 5 as an example, phase correction data of the second virtual channel of the slice of the target site is phase correction data of the main virtual channel of the slice of the target site.

In an optional embodiment, step 406 may additionally or alternatively comprise: calculating a phase difference between a first echo and each subsequent echo (i.e. a second echo and each echo thereafter) of the main virtual channel of the slice, respectively, according to phase correction data of each subsequent echo (i.e. a second echo and each echo thereafter) of the main virtual channel of the slice, with reference to phase correction data of the first echo of the main virtual channel of the slice of the target site; and performing phase correction on the multi-segment image data of each subsequent echo (i.e. a second echo and each echo thereafter) of each virtual channel of the slice of the target site, according to the calculated phase difference between the first echo and each subsequent echo (i.e. a second echo and each echo thereafter) of the main virtual channel of the slice.

Taking FIG. 5 as an example, the main virtual channel is the second virtual channel, then for a certain slice a of the target site, the slice a is set to contain a total of b-segment image data, and b>1, then a phase difference between the first echo and the second echo and each echo thereafter of the second virtual channel of the slice a is calculated, respectively, according to phase correction data of the second echo and each thereafter of the second virtual channel of the slice a of the target site, with reference to phase correction data of the first echo of the second virtual channel of the slice a of the target site; then, phase correction is performed on the multi-segment image data of the second echo and each echo thereafter of each virtual channel of the slice a of the target site, according to the calculated phase difference between the first echo and the second echo and each echo thereafter of the second virtual channel of the slice a.

In an optional embodiment, after step 406, the method further comprises: when phase correction has been completed for the multi-segment image data of each virtual channel of each slice of the target site, using a parallel imaging algorithm to perform image reconstruction on the multi-segment image data of each virtual channel of each slice of the target site after phase correction, to obtain an MR image.

The above embodiments have beneficial technical effects, some being provided below as examples.

For each slice of the target site: performing a calculation on ACS of each physical channel of the slice of the target site, to obtain a channel compression matrix of the slice and ACS of cach virtual channel of the slice; the channel compression matrix of the slice is used to perform channel compression on phase correction data of each physical channel of the slice, to obtain phase correction data of each virtual channel of the slice; a channel compression matrix of the slice is used to perform channel compression on the multi-segment image data of each physical channel of the slice, to obtain multi-segment image data of cach virtual channel of the slice; the virtual channel containing optimal ACS information of the slice is taken to be the main virtual channel of the slice, so that: the main virtual channel is the channel containing the optimal ACS information. Thereafter, phase correction data of the main virtual channel of the slice of the target site is used to perform phase correction on multi-segment image data of each virtual channel of the slice of the target site, so that: phase correction data of the main virtual channel containing phase correction data of the highest quality in each slice is used to perform phase correction on multi-segment image data of all virtual channels of the slice, avoiding phase correction errors due to phase correction data of poor quality, while also avoiding additional phase differences introduced between channels during a phase correction process, i.e. reducing phase errors in multi-segment image data, and finally reducing artifacts in an MR image obtained by parallel imaging reconstruction, improving the quality of the MR image.

It should be noted that, in embodiments of the present disclosure, steps 401-406 may be performed while scanning. Thus, while the target site is being scanned, ACS of cach physical channel is first acquired slice by slice, then the phase correction data of each physical channel is acquired slice by slice, and then the multi-segment image data of cach physical channel is acquired slice by slice, so that, after ACS of each physical channel of a certain slice has been acquired, step 402 is performed, and after the phase correction data of each physical channel of the slice has been acquired, step 403 is performed, and after the multi-segment image data of each physical channel of the slice has been further acquired, steps 404-406 are performed.

In an application, for example, a first spin echo sequence of a single excitation can be used respectively to scan each slice of the target site to obtain ACS of each physical channel of each slice of the target site. That is, ACS of each physical channel of one of the slices of the target site is acquired per excitation.

A second spin echo sequence of a single excitation without a phase-encoding gradient applied can be used respectively to scan each slice of the target site to obtain phase correction data of each physical channel of each slice of the target site. That is, each excitation acquires phase correction data of each physical channel of one of the slices of the target site. For example, the target site has 1 slices, a total of m physical channels are activated per excitation, a spin echo sequence of a single excitation contains 1 RF pulse and n refocusing pulses, then for any slice of the target site, in a single excitation corresponding to the slice, each channel respectively acquires n phase correction data lines.

A segment spin echo sequence of multiple excitations can be used respectively to perform segment scanning on each slice of the target site to obtain phase correction data of each physical channel of each slice of the target site. For example, when a TSE sequence is used, due to the requirements for set scanning parameters, such as resolution, echo train, etc., when image data of a slice of the target site is acquired, multiple excitations are required to scan a slice, wherein each excitation obtains a segment of a slice, and segments of multiple excitations of a slice are combined to obtain a complete dataset of a slice. For example, the target site has 1 slices, a total of m physical channels are used per excitation, a spin echo sequence of a single excitation contains 1 RF pulse and n refocusing pulses, and p excitations are required per slice, then for any slice of the target site, in a corresponding excitation of the slice, n lines are acquired for each channel, respectively, and after p excitations are completed, for any channel of the slice, p lots of n lines acquired in p excitations of the channel of the slice are merged, to obtain a k-space containing p*n lines; that is, cach channel of each slice respectively corresponds to a k-space containing p*n lines.

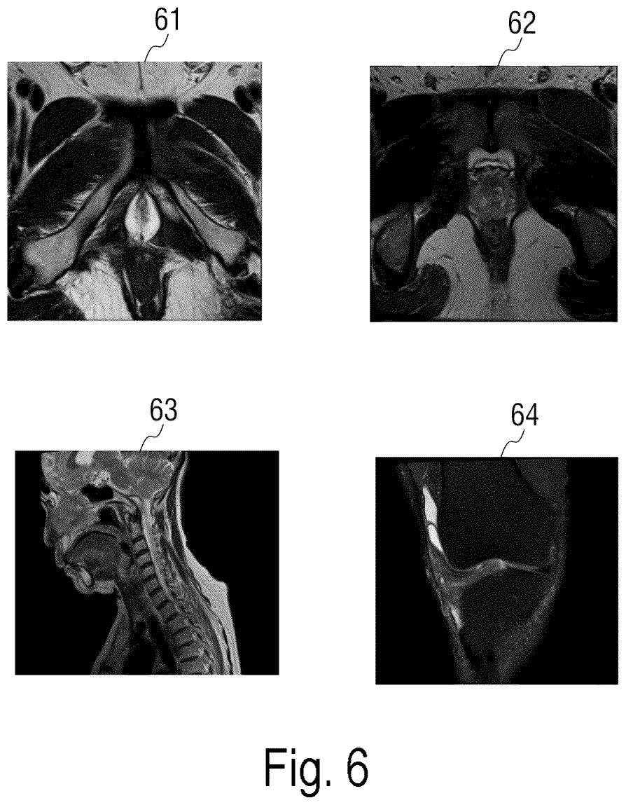

FIG. 6 illustrates an example of MR images obtained by using an embodiment of the present disclosure to perform phase correction on acquired multi-segment image data, and then performing image reconstruction on the phase-corrected multi-segment image data using a parallel imaging method, in an application example of the present disclosure. The target sites corresponding to 61-64 are identical to 11-14, respectively, and it can be seen that:
in a comparison with 11-14, the artifacts in 11-14 are absent in 61-64, because: for each slice, phase correction data of the main virtual channel containing the optimal phase correction data of the slice is used to perform phase correction on multi-segment image data of all the virtual channels of the slice, so that an additional phase difference is not introduced between channels, thereby eliminating artifacts in the final MR image.

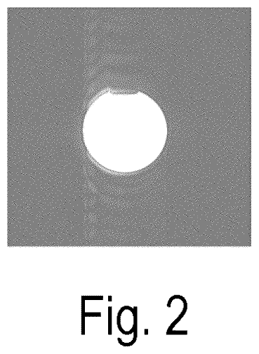

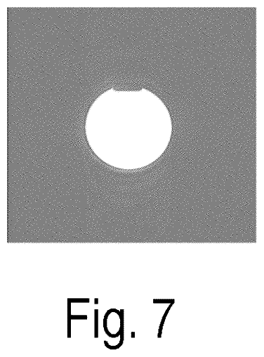

FIG. 7 illustrates an example of an MR image obtained by using an embodiment of the present disclosure to perform phase correction on acquired multi-segment image data, and then performing image reconstruction on the phase-corrected multi-segment image data using a parallel imaging method, in another application example of the present disclosure. The imaging target is the same as in FIG. 2, being a water phantom in both cases. It can be seen that: in a comparison with FIG. 2, the artifacts in FIG. 2 are greatly reduced in FIG. 7, because: phase correction data of the main virtual channel containing the optimal phase correction data is used to perform phase correction on multi-segment image data of all the virtual channels, so that phase correction errors between echoes are reduced, thereby reducing artifacts in the final MR image.

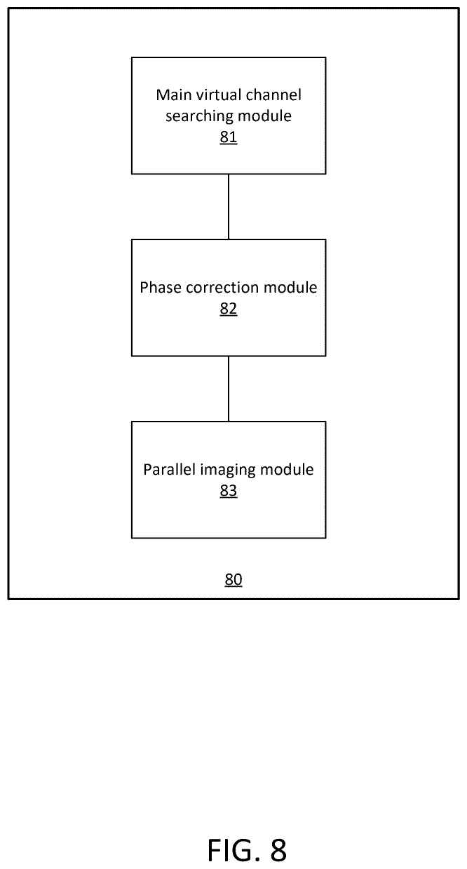

FIG. 8 illustrates a structural schematic diagram of a phase correction apparatus for MR imaging as provided in an embodiment of the present disclosure. The apparatus may for instance comprise a main virtual channel searching module 81 (also referred to herein as a main virtual channel searching circuitry) and a phase correction module 82 (also referred to herein as phase correction circuitry), wherein:
a main virtual channel searching module 81 configured to: for each slice of a target site, use a channel compression algorithm to determine each virtual channel of the slice using a channel compression matrix; and determining a main virtual channel of the slice from each virtual channel; and
a phase correction module 82 configured to: for each slice of the target site, use phase correction data of the main virtual channel of the slice of the target site to perform phase correction on multi-segment image data of each virtual channel of the slice of the target site.

In an optional embodiment, the main virtual channel searching module 81 may additionally or alternatively be used for: for each slice of the target site, to use a channel compression algorithm to perform a calculation on ACS of each physical channel of the slice of the target site, to obtain a channel compression matrix of the slice of the target site, and to use the channel compression matrix to obtain ACS of each virtual channel of the slice of the target site; and to search all the virtual channels of the slice for a virtual channel containing optimal ACS information, according to ACS of each virtual channel of the slice of the target site, and to select the virtual channel containing the optimal ACS information to be the main virtual channel of the slice.

In an optional embodiment, the phase correction module 82 may additionally or alternatively be used for: for each slice of the target site, use a channel compression matrix of the slice of the target site to perform channel compression on phase correction data of cach physical channel of the slice of the target site, to obtain phase correction data of each virtual channel of the slice of the target site; using the channel compression matrix of the slice of the target site to perform channel compression on multi-segment image data of each physical channel of the slice of the target site, to obtain multi-segment image data of cach virtual channel of the slice of the target site; and to use the phase correction data of the main virtual channel of the slice of the target site to perform phase correction on the multi-segment image data of each virtual channel of the slice of the target site.

In an optional embodiment, the phase correction apparatus 80 further comprises: a parallel imaging module 83 (also referred to herein as parallel imaging circuitry), configured to execute a parallel imaging algorithm to perform image reconstruction on the multi-segment image data of each virtual channel of each slice of the target site after phase correction, to obtain an MR image.

In an optional embodiment, the channel compression algorithm used by the main virtual channel searching module 81 may for example include a GCC algorithm, an SCC algorithm, a mode matrix algorithm, etc.

In an optional embodiment, the main virtual channel searching module 81 searching all the virtual channels of the slice for a virtual channel containing optimal ACS information, according to ACS of each virtual channel of the slice of the target site, and taking the virtual channel containing the optimal ACS information to be the main virtual channel of the slice comprises: searching for ACS with the largest amplitude in all k-spaces where ACS of all virtual channels of the slice of the target site is located, and taking the virtual channel where the ACS with the largest amplitude is located to be the main virtual channel; or, respectively calculating the sum of squares for a preset number of ACS of each k-space central region where the ACS of each virtual channel of the slice of the target site are located, searching for a maximum value in the sum of squares corresponding to each virtual channel, and taking the virtual channel where the maximum value is located to be the main virtual channel.

In an optional embodiment, the phase correction module 82 using phase correction data of the main virtual channel of the slice of the target site to perform phase correction on multi-segment image data of each virtual channel of the slice of the target site comprises: calculating a phase difference between a first echo and each subsequent echo of the main virtual channel of the slice, respectively, according to phase correction data of each subsequent echo of the main virtual channel of the slice, with reference to phase correction data of the first echo of the main virtual channel of the slice of the target site; and performing phase correction on the multi-segment image data of each subsequent echo of each virtual channel of the slice of the target site, according to the calculated phase difference between the first echo and each subsequent echo of the main virtual channel of the slice.

Embodiments of the present disclosure further provide an MR imaging system; the MR imaging system comprises the phase correction apparatus 80 for MR imaging as described in any one of the embodiments above.

It should be noted that the phase correction method and apparatus for MR imaging, and the MR imaging system provided by the embodiments of the present disclosure may be a method, an apparatus, and a system that are all applied in medical imaging.

Embodiments of the present disclosure further provide a computer program product, comprising a computer program or instruction, which, when executed by a processor, controller, processing circuitry, etc., executes or otherwise performs any of the steps of the phase correction process flows for MR imaging as described in any one of the above embodiments.

Embodiments of the present disclosure further provide a computer-readable storage medium, wherein the computer-readable storage medium stores an instruction, and the instruction, when executed by a processor, can execute any of the steps of the phase correction method for MR imaging as described above. In various applications, the computer-readable medium may be included in each device/apparatus/system in the above embodiments, or may exist independently without being assembled into the device/apparatus/system. Instructions may be stored in the computer-readable storage medium, and the instructions, when executed by a processor, controller processing circuity, etc., can execute any of the steps of the phase correction process flows for MR imaging as described above.

Embodiments of the present disclosure further provide an electronic device. The electronic device may include a processor with one or more processing cores, a memory with one or more computer-readable storage media, and a computer program stored in the memory and executable on the processor. When the program in the memory is executed, any portion or the entirety of the phase correction process flows for MR imaging described above may be implemented.

Those skilled in the art will understand that features stated in various embodiments and/or claims of the present application can be combined and/or integrated in various ways, even if such combinations or integrations are not clearly stated in the present application. In particular, without departing from the spirit and teaching of the present application, features stated in embodiments and/or claims of the present application can be combined and/or integrated in various ways, and all such combinations and/or integrations fall within the scope of disclosure of the present application.

Example embodiments have been used herein to expound the principles and forms of implementation of the present application, but the description of the embodiments above is merely intended to help understand the method of the present application and the core idea thereof, not to restrict the present application. Those skilled in the art can make changes in terms of the specific implementation and application scope, based on the idea, spirit, and principles of the present application, and any modifications, equivalent replacements, improvements, etc. made thereby should be included within the scope of protection of the present application.

The various components described herein may be referred to as “modules.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, as applicable and relevant, may alternatively be referred to herein as “circuitry,” “controllers,” “processors,” or “processing circuitry,” or alternatively as noted herein.

What is claimed is:

1. A phase correction method for magnetic resonance imaging, comprising:
for each slice of a target site:
performing channel compression to determine each virtual channel of the slice using a channel compression matrix;
determining a main virtual channel of the slice from each virtual channel; and
using phase correction data of the main virtual channel of the slice of the target site to perform phase correction on multi-segment image data of each virtual channel of the slice of the target site.

2. The method as claimed in claim 1, wherein performing the channel compression comprises executing a channel compression algorithm to perform a calculation on an auto-calibration signal (ACS) of each physical channel of the slice of the target site to obtain a channel compression matrix of the slice of the target site, and using the channel compression matrix to obtain an ACS of each virtual channel of the slice of the target site, and
wherein determining the main virtual channel of the slice comprises searching the virtual channels of the slice for a virtual channel containing optimal ACS information according to the ACS of each virtual channel of the slice of the target site, and selecting the virtual channel containing the optimal ACS information as the main virtual channel of the slice.

3. The method as claimed in claim 1, wherein using the phase correction data of the main virtual channel of the slice of the target site comprises:
using a channel compression matrix of the slice of the target site to perform channel compression on phase correction data of each physical channel of the slice of the target site to obtain phase correction data of each virtual channel of the slice of the target site;
using the channel compression matrix of the slice of the target site to perform channel compression on multi-segment image data of each physical channel of the slice of the target site to obtain multi-segment image data of each virtual channel of the slice of the target site; and
using the phase correction data of the main virtual channel of the slice of the target site to perform phase correction on the multi-segment image data of each virtual channel of the slice of the target site.

4. The method as claimed in claim 1, further comprising:
after using the phase correction data of the main virtual channel of the slice of the target site, executing a parallel imaging algorithm to perform image reconstruction on the multi-segment image data of each virtual channel of each slice of the target site after phase correction to obtain a magnetic resonance image.

5. The method as claimed in claim 2, wherein the channel compression algorithm comprises a geometric channel/coil compression (GCC) algorithm, a single coil compression (SCC) algorithm, or a mode matrix algorithm.

6. The method as claimed in claim 2, wherein the searching the virtual channels of the slice for the virtual channel containing optimal ACS information according to ACS of each virtual channel of the slice of the target site, and selecting the virtual channel containing the optimal ACS information to be the main virtual channel of the slice comprises:
searching for an ACS having the largest amplitude in respective k-spaces where the ACS of virtual channels of the slice is located, and selecting the virtual channel where the ACS having the largest amplitude is located as the main virtual channel of the slice.

7. The method as claimed in claim 2, wherein the searching the virtual channels of the slice for the virtual channel containing optimal ACS information according to ACS of each virtual channel of the slice of the target site, and selecting the virtual channel containing the optimal ACS information to be the main virtual channel of the slice comprises:
respectively calculating a sum of squares for a preset number of ACSs of each k-space central region where the ACS of each virtual channel of the slice is located, searching for a maximum value in the sum of squares corresponding to each virtual channel, and selecting the virtual channel where the maximum value is located as the main virtual channel of the slice.

8. The method as claimed in claim 1, wherein using the phase correction data of the main virtual channel of the slice of the target site comprises:
calculating a phase difference between a first echo and each subsequent echo of the main virtual channel of the slice, respectively, according to phase correction data of each subsequent echo of the main virtual channel of the slice, with reference to phase correction data of the first echo of the main virtual channel of the slice of the target site; and
performing phase correction on multi-segment image data of each subsequent echo of each virtual channel of the slice of the target site according to the calculated phase difference between the first echo and each subsequent echo of the main virtual channel of the slice.

9. A phase correction apparatus for magnetic resonance imaging, characterized in that the apparatus comprises:
main virtual channel searching circuitry configured to, for each slice of a target site:
perform a channel compression to determine each virtual channel of the slice using a channel compression matrix; and
determine a main virtual channel of the slice from each virtual channel; and
phase correction circuitry configured to, for each slice of the target site:
utilize phase correction data of the main virtual channel of the slice of the target site to perform phase correction on multi-segment image data of each virtual channel of the slice of the target site.

10. The apparatus as claimed in claim 9, wherein the main virtual channel searching circuitry is configured to:
perform the channel compression by executing a channel compression algorithm to perform a calculation on an auto-calibration signal (ACS) of each physical channel of the slice of the target site to obtain a channel compression matrix of the slice of the target site, and to utilize the channel compression matrix to obtain an ACS of each virtual channel of the slice of the target site; and
determine the main virtual channel of the slice by searching the virtual channels of the slice for a virtual channel containing optimal ACS information according to the ACS of each virtual channel of the slice of the target site, and selecting the virtual channel containing the optimal ACS information as the main virtual channel of the slice.

11. The apparatus as claimed in claim 9, wherein the main virtual channel searching circuitry is configured to utilize the phase correction data of the main virtual channel of the slice of the target site by:
using a channel compression matrix of the slice of the target site to perform channel compression on phase correction data of each physical channel of the slice of the target site to obtain phase correction data of each virtual channel of the slice of the target site;
using the channel compression matrix of the slice of the target site to perform channel compression on multi-segment image data of each physical channel of the slice of the target site to obtain multi-segment image data of each virtual channel of the slice of the target site; and
using the phase correction data of the main virtual channel of the slice of the target site to perform phase correction on the multi-segment image data of each virtual channel of the slice of the target site.

12. The apparatus as claimed in claim 9, further comprising:
parallel imaging circuitry configured to, after using the phase correction data of the main virtual channel of the slice of the target site, execute a parallel imaging algorithm to perform image reconstruction on the multi-segment image data of each virtual channel of each slice of the target site after phase correction to obtain a magnetic resonance image.

13. The apparatus as claimed in claim 10, wherein the channel compression algorithm comprises a geometric channel/coil compression (GCC) algorithm, a single coil compression (SCC) algorithm, or a mode matrix algorithm.

14. The apparatus as claimed in claim 10, wherein the main virtual channel searching circuitry is configured to search the virtual channels of the slice for the virtual channel containing optimal ACS information according to ACS of each virtual channel of the slice of the target site, and to select the virtual channel containing the optimal ACS information to be the main virtual channel of the slice by:
searching for an ACS having the largest amplitude in respective k-spaces where the ACS of virtual channels of the slice is located, and selecting the virtual channel where the ACS having the largest amplitude is located as the main virtual channel of the slice.

15. The apparatus as claimed in claim 10, wherein the main virtual channel searching circuitry is configured to search the virtual channels of the slice for the virtual channel containing optimal ACS information according to ACS of each virtual channel of the slice of the target site, and to select the virtual channel containing the optimal ACS information to be the main virtual channel of the slice by:
respectively calculating a sum of squares for a preset number of ACSs of each k-space central region where the ACS of each virtual channel of the slice is located, searching for a maximum value in the sum of squares corresponding to each virtual channel, and selecting the virtual channel where the maximum value is located as the main virtual channel of the slice.

16. The apparatus as claimed in claim 9, wherein the phase correction circuitry is configured to utilize the phase correction data of the main virtual channel of the slice of the target site by calculating a phase difference between a first echo and each subsequent echo of the main virtual channel of the slice, respectively, according to phase correction data of each subsequent echo of the main virtual channel of the slice, with reference to phase correction data of the first echo of the main virtual channel of the slice of the target site.
